(19) United States
(12) Patent Application Publication
(10) Pub. No.: US 2025/0357302 A1
(43) Pub. Date: Nov. 20, 2025

(54) METHOD FOR FORMING SEMICONDUCTOR PACKAGE WITH VARIABLE PILLAR HEIGHT

(71) Applicant: Taiwan Semiconductor Manufacturing Company Limited, Hsinchu (TW)

(72) Inventors: Li-Ling Liao, Hsinchu City (TW); Ming-Chih Yew, Hsinchu City (TW); Po-Chen Lai, Hsinchu (TW); Chia-Kuei Hsu, Hsinchu City (TW); Shin-Puu Jeng, Po-Shan Village (TW); Meng-Liang Lin, Hsinchu (TW)

(21) Appl. No.: 19/287,950

(22) Filed: Aug. 1, 2025

Related U.S. Application Data
(62) Division of application No. 17/828,066, filed on May 31, 2022.

(51) Int. Cl. H01L 23/498; H01L 21/48; H01L 23/00; H01L 23/14; H01L 25/065

(52) U.S. Cl. CPC H01L 23/49838; H01L 21/4853; H01L 23/145; H01L 23/49811; H01L 23/49833; H01L 25/0655; H01L 23/49816; H01L 24/16; H01L 24/32; H01L 24/73; H01L 2224/16227; H01L 2224/16238; H01L 2224/32225; H01L 2224/73204; H01L 2924/3511; H01L 2924/35121

(57) ABSTRACT

Semiconductor packages and methods of fabricating semiconductor packages include bonding structures on a surface of an interposer having non-uniform height dimensions in different regions of the interposer. A plurality of solder connections may contact the pillars and electrically connect the respective pillars of the interposer to corresponding bonding structures on a package substrate. The variation in the heights of the pillars in different regions of the interposer may compensate for warping of the interposer and improve the reliability of the electrical connections between the interposer and the package substrate.

### CROSS-REFERENCE TO RELATED APPLICATIONS

This application is a divisional application of U.S. patent application Ser. No. 17/828,066 entitled “Semiconductor Package with Variable Pillar Height and Methods for Forming the Same,” filed on May 31, 2022, the entire contents of which is hereby incorporated by reference for all purposes.

### BACKGROUND

Semiconductor devices are used in a variety of electronic applications. Some example uses may include personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer, and individual dies on the wafer are singulated by sawing between the integrated circuits along a scribe line. The individual dies are typically packaged separately, for example, in multi-chip modules, or in other types of packaging.

As semiconductor packages have become more complex, ensuring mechanical integrity of the package, including the electrical interconnections between various components of the package, has become more difficult.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-section view of an exemplary intermediate structure during a process of forming a semiconductor package including an organic interposer located over a first carrier substrate according to various embodiments of the present disclosure.

FIG. 2 is a vertical cross-section view of the exemplary intermediate structure showing bonding structures located over the first side surface of the interposer according to various embodiments of the present disclosure.

FIG. 3 is a vertical cross-section view of the exemplary intermediate structure showing a plurality of semiconductor integrated circuit (IC) dies mounted over the first side surface of the interposer according to various embodiments of the present disclosure.

FIG. 4 is a vertical cross-section view of the exemplary intermediate structure showing a first underfill material portion located between the lower surfaces of the semiconductor IC dies and the first side surface of the interposer, and a molding portion around the outer periphery of the plurality of semiconductor IC dies according to various embodiments of the present disclosure.

FIG. 5 is a vertical cross-section view of the exemplary intermediate structure showing a second release layer located over the upper surfaces of the plurality of semiconductor dies, the exposed upper surface of the first underfill material portion and the exposed upper surface of the molding portion, and a second carrier substrate over the second release layer according to various embodiments of the present disclosure.

FIG. 6 is a vertical cross-section view of the exemplary intermediate structure showing the first carrier substrate removed according to various embodiments of the present disclosure.

FIG. 7A is a vertical cross-section view of the exemplary intermediate structure showing a plurality of pillars having different height dimensions located over the second side surface of the interposer according to various embodiments of the present disclosure.

FIG. 7B is a top view of the exemplary intermediate structure of FIG. 7A.

FIG. 7C is an enlarged vertical cross-section view of the exemplary intermediate structure illustrating a pair of pillars having different height dimensions according to various embodiments of the present disclosure.

FIG. 8A is a vertical cross-section view an exemplary intermediate structure showing plurality of pillars having three different height dimensions located over the second side surface of the interposer according to various embodiments of the present disclosure.

FIG. 8B is a top view of the exemplary intermediate structure of FIG. 8A.

FIG. 8C is an enlarged vertical cross-section view of an exemplary intermediate structure illustrating pillars having three different height dimensions according to various embodiments of the present disclosure.

FIG. 9A is a top view of an exemplary intermediate structure illustrating an alternative arrangement of pillars having non-uniform height dimensions according to various embodiments of the present disclosure.

FIG. 9B is a top view of an exemplary intermediate structure illustrating another alternative arrangement of pillars having non-uniform height dimensions according to various embodiments of the present disclosure.

FIG. 9C is a top view of an exemplary intermediate structure illustrating another alternative arrangement of pillars having non-uniform height dimensions according to various embodiments of the present disclosure.

FIGS. 10A-10H are sequential vertical cross-section views illustrating an exemplary process of forming pillars having different height dimensions over the second side surface of the interposer according to various embodiments of the present disclosure.

FIG. 11 is a vertical cross-section view of the exemplary intermediate structure showing a package structure according to various embodiments of the present disclosure.

FIG. 12 is a vertical cross-section view of the exemplary intermediate structure showing the package structure mounted over the front side surface of a package substrate according to various embodiments of the present disclosure.

FIG. 13 is a vertical cross-section view of a semiconductor package including a second underfill material portion located between the front side surface of the package substrate and the second side surface of the interposer according to various embodiments of the present disclosure.

FIG. 14 is a vertical cross-section view of the semiconductor package including a plurality of solder balls located on the rear side surface of the package substrate according to various embodiments of the present disclosure.

FIG. 15 is a vertical cross-section view of a semiconductor package including a semiconductor material interposer according to another embodiment of the present disclosure.

FIG. 16 is a flow diagram illustrating a method of fabricating a semiconductor package according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein may be directed to semiconductor devices, and in particular to semiconductor packages and methods of fabricating semiconductor packages having bonding structures (which may also be referred to as “pillars”) on a surface of an interposer having non-uniform height dimensions in different regions of the interposer.

Typically, in a semiconductor package a number of semiconductor integrated circuit (IC) dies (i.e., “chips”) may be mounted onto a common substrate, which may also be referred to as a “package substrate.” In some packages, such as in a fan out wafer level package (FOWLP) and/or fan-out panel level package (FOPLP), a plurality of semiconductor IC dies may be mounted to an interposer, such as an organic interposer or a semiconductor (e.g., silicon) interposer, that may include interconnect structures extending therethrough. The resulting package structure, including the interposer and the semiconductor IC dies mounted thereon, may then be mounted onto a surface of a package substrate using solder connections.

Many semiconductor packages, such as semiconductor packages used for high-performance computing (HPC) application, may include a large number of IC dies integrated in the semiconductor package. The inclusion of the large number of IC dies may induce mechanical stress and the warping of the interposer and/or of the package substrate. As the interposer and/or the package substrate warp, the potential for defective solder connections between these components increases, such as instances of solder cold joints in which insufficient melting of the solder material provides a poor bond that is susceptible to cracking and separation.

In order to improve the reliability of the electrical connections within semiconductor packages, various embodiments disclosed herein include semiconductor packages and methods of fabricating semiconductor packages that include bonding structures (which may also be referred to as “pillars”) on a surface of the interposer having non-uniform height dimensions in different regions of the interposer. A plurality of solder connections may contact the pillars and electrically connect the respective pillars of the interposer to corresponding bonding structures on a surface of the package substrate. The variation in the heights of the pillars in different regions of the interposer may compensate for warping of the interposer away from and/or warping of the interposer closer to the package substrate. For example, as the interposer warps away from the package substrate, the pillar of increased heights in the area of the warpage may compensate for the warpage away. In contrast, as the interposer warps closer to the package substrate, the pillar of decreased height may provide the space for the warpage towards the package substrate. By varying the heights of the pillars, the uniformity of the gaps between the respective pillars and the corresponding bonding structures on a surface of the package substrate may be improved, thereby improving the reliability of the electrical connections between the interposer and the package substrate.

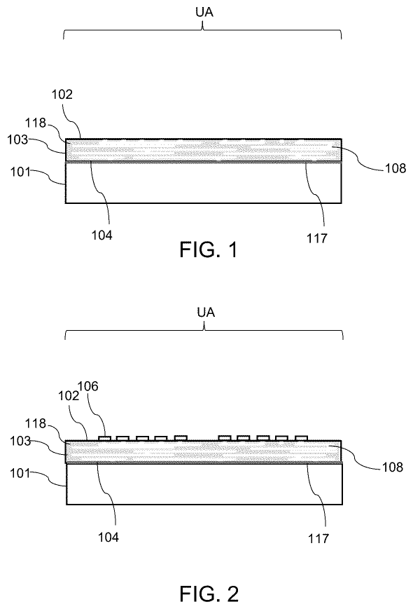

FIG. 1 is a vertical cross-section view of an exemplary intermediate structure during a process of forming a semiconductor package according to various embodiments of the present disclosure. Referring to FIG. 1, the exemplary intermediate structure includes a first carrier substrate 101 and an interposer 103 formed and mounted over a front side surface of the first carrier substrate 101. The first carrier substrate 101 may provide mechanical support to the interposer 103, and may be formed of a suitable substrate material, such as glass material, a ceramic material (e.g., a sapphire substrate), a semiconductor material (e.g., a silicon substrate), or the like. Other suitable materials for the first carrier substrate 101 are within the contemplated scope of disclosure. In some embodiments, the first carrier substrate 101 may be formed of an optically transparent material.

In some embodiments, a first release layer 117 may be located over the front side surface of the first carrier substrate 101, and the interposer 103 may be located over the first release layer 117. The first release layer 117 may include an adhesive material that may adhere the interposer 103 to the front side surface of the first carrier substrate 101. In some embodiments, the first release layer 117 may include an adhesive material that may be subsequently treated to cause the adhesive material of the first release layer 117 lose its adhesive properties, such that the first carrier substrate 101 may be separated from the interposer 103. In some embodiments, the adhesive material of the first release layer 117 may lose its adhesive properties when subjected to treatment using an energy source, such as a thermal, optical (e.g., UV, laser, etc.) and/or sonic (e.g., ultrasonic) energy source. In one non-limiting example, the first release layer 117 may include a light-to-heat conversion (LTHC) material that may selectively absorb optical radiation in certain wavelength range(s), such as ultraviolet radiation, causing the LTHC material to heat up and thereby lose adhesion. In other embodiments in which the first carrier substrate 101 is formed of an optically transparent material, the application of an optical energy source may cause the first release layer 117 to lose its adhesive property. Alternatively, the first release layer 117 may include an adhesive material, such as an acrylic pressure-sensitive adhesive material, that may decompose when subjected to an elevated temperature. Other suitable materials for the first release layer 117 are within the contemplated scope of disclosure.

Referring again to FIG. 1, the interposer 103 may include a first side surface 102 and a second side surface 104 opposite the first side surface 102. The second side surface 104 of the interposer 103 may face the front side surface of the first carrier substrate 101. A plurality of conductive interconnect structures 108 (e.g., metal lines and vias) may extend within the interposer 103 between the first side surface 102 and the second side surface 104 of the interposer 103. The conductive interconnect structures 108 may be formed in and surrounded by an insulating matrix that may be composed of a dielectric material 118. The conductive interconnect structures 108 of the interposer 103 may be configured to route electrical signals between semiconductor integrated circuit (IC) dies and a package substrate in a semiconductor package to be subsequently formed. Thus, the conductive interconnect structures 108 of the interposer 103 may also be referred to as “redistribution structures.”

In some embodiments, the interposer 103 may be an organic interposer. The organic interposer 103 may be formed on the first carrier substrate 101. In one non-limiting example, the interposer 103 may be formed by sequentially depositing layers of a dielectric material 118, such as a dielectric polymer material, over the front side surface of the first carrier substrate 101 (and over the first release layer 117, if present). Each of the layers of dielectric material 118 may be lithographically patterned and etched to form open regions (e.g., trenches and/or via openings), and a metallization process may then be used to fill the open regions and form conductive interconnect structures 108 (e.g., metal lines and vias) within each successive layer of dielectric material 118. In this manner, the interposer 103 may be built layer-by-layer over the front side surface of the first carrier substrate 101.

In some embodiments, each of the layers of dielectric material 118 of the interposer 103 may include a suitable dielectric polymer material, such as polyimide (PI), benzocyclobutene (BCB), or polybenzobisoxazole (PBO). Other suitable dielectric materials are within the contemplated scope of disclosure. The layers of dielectric material 118 of the interposer 103 may be formed using a suitable deposition process, such as a spin coating and drying process. Other suitable deposition processes are within the contemplated scope of disclosure.

The conductive interconnect structures 108 of the interposer 103 may be formed of a suitable conductive material, such as Cu, Ni, W, Cu, Co, Mo, Ru, etc., including alloys and combinations of the same. In some embodiments, the conductive interconnect structures 108 may include a metallic barrier layer, such as a layer of Ti, TiN, TaN, or WN, contacting the dielectric material 118, and a metallic fill material, which may include an elemental metal (e.g., Cu, Ni, etc.) or an alloy or a combination thereof. Other suitable materials for the conductive interconnect structures 108 of the interposer 103 are within the contemplated scope of disclosure. The conductive interconnect structures 108 of the interposer 103 may be formed using any suitable deposition process. For example, suitable deposition processes may include physical vapor deposition (PVD), sputtering, chemical vapor deposition (CVD), atomic layer deposition (ALD), plasma-enhanced chemical vapor deposition (PECVD), electrochemical deposition (e.g., electroplating), or combinations thereof.

Referring again to FIG. 1, an instance of an interposer 103 located over the front side surface of the first carrier substrate 101 may be referred to as a unit area (UA) of the first carrier substate 101. A single unit area (UA) is illustrated in FIG. 1, although it will be understood that the first carrier substrate 101 may include a plurality of unit areas (UAs), where each unit area (UA) may include a separate instance of an interposer 103 over the front side surface of the first carrier substrate 101. For example, the first carrier substrate 101 may include a periodic two-dimensional array (such as a rectangular array) of unit areas (UAs), where each unit area (UA) of the array may include a separate instance of an interposer 103 over the front side surface of the carrier substrate 101. In some embodiments, each interposer 103 within a unit area (UA) of the array may have an identical structure. The plurality of interposers 103 over the first carrier substrate 101 may be continuous with one another, such that a continuous layer of dielectric material 118 may extend over the front side surface of the first carrier substrate 101, with separate instances of conductive interconnect structures 108 formed within the continuous layer of dielectric material 118 in each unit area (UA).

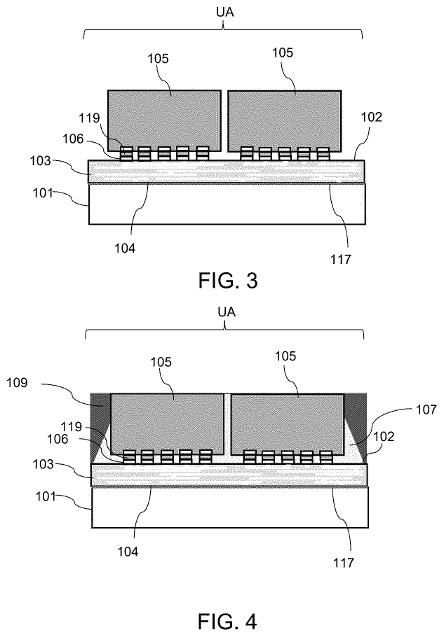

FIG. 2 is a vertical cross-section view of the exemplary intermediate structure showing interposer bonding structures 106 located over the first side surface 102 of the interposer 103 according to various embodiments of the present disclosure. Referring to FIG. 2, the interposer bonding structures 106 may include a plurality of metallic bumps. The interposer bonding structures 106 may be formed by depositing one or more layers of a metal material and patterning the one or more layers of metal material to form the plurality of interposer bonding structures 106 over the first side surface 102 of the interposer 103. Each bonding structure 106 may be electrically coupled to an underlying conductive interconnect structure 108 of the interposer 103. In some embodiments, the interposer bonding structures 106 may form at least one periodic two-dimensional array (such as a rectangular array) of interposer bonding structures 106 within the unit area (UA). In some embodiments, a plurality of interposer bonding structures 106 may be formed over the first side surface 102 of the interposer 103 in each unit area (UA) of the first carrier substrate 101.

In various embodiments, the interposer bonding structures 106 may be configured for subsequent microbump bonding (i.e., C2 bonding) to corresponding bonding structures formed on semiconductor integrated circuit (IC) dies. In some embodiments, the interposer bonding structures 106 may include a plurality of metal pillars. The metal pillars may include copper or a copper-containing alloy. In some embodiments, the bonding structures may include a plurality of metal stacks, such as a plurality of Cu—Ni—Cu stacks. In some embodiments, the interposer bonding structures 106 may include a solder material, such as tin or a tin-containing alloy, on an upper surface of the interposer bonding structures 106. Other suitable materials and/or configurations for the interposer bonding structures 106 are within the contemplated scope of disclosure.

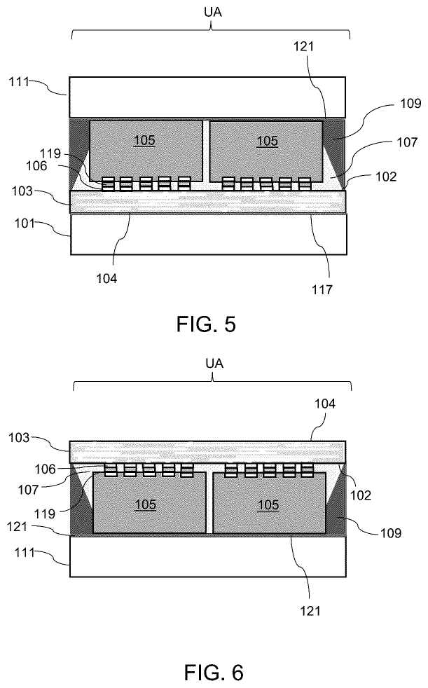

FIG. 3 is a vertical cross-section view of the exemplary intermediate structure showing a plurality of semiconductor integrated circuit (IC) dies 105 mounted over the first side surface 102 of the interposer 103 according to various embodiments of the present disclosure. In some embodiments, the plurality of IC semiconductor dies 105 may include at least one system-on-chip (SoC) die. An SoC die may include, for example, an application processor die, a central processing unit die, and/or a graphic processing unit die. In some embodiments, the plurality of IC semiconductor dies 105 may include at least one memory die. The at least one memory die may include a high bandwidth memory (HBM) die. In some embodiments, a HBM die may include a vertical stack of interconnected memory dies. Alternatively, or in addition, the at least one memory die may include a dynamic random access memory (DRAM) die. In some embodiments, the plurality of semiconductor IC dies 105 may be homogeneous, meaning that all of the semiconductor IC dies 105 may be of the same type (e.g., all SoC dies, all HBM dies, all DRAM dies, etc.). Alternatively, the plurality of semiconductor IC dies 105 may be heterogeneous, meaning that the plurality of semiconductor IC dies 105 may include different types of semiconductor IC dies 105 (e.g., at least one SoC die and at least one memory die). In some embodiments, the plurality of semiconductor IC dies 105 may include one or more SoC dies and a plurality of HBM dies. The one or more SoC dies may be located in a central portion of the unit area (UA) and the plurality of HBM dies may laterally surround the one or more SoC dies. Further, although two semiconductor IC dies 105 are shown mounted over the first side surface 102 of the interposer 103 in the exemplary embodiment of FIG. 3, it will be understood that in various embodiments more than two semiconductor IC dies 105 may be mounted over the first side surface 102 of the interposer 103.

Referring again to FIG. 3, each of the semiconductor IC dies 105 may include a plurality of semiconductor die bonding structures 119 located over a lower surface of the semiconductor IC die 105. The semiconductor die bonding structures 119 on the semiconductor IC dies 105 may have a similar or identical configuration as the interposer bonding structures 106 over the first side surface 102 of the interposer 103 described above with reference to FIG. 2. For example, the semiconductor die bonding structures 119 on the lower surfaces of the semiconductor IC dies 105 may include a plurality of metallic bumps, such as metal pillars and/or metal stacks. In some embodiments, the semiconductor die bonding structures 119 on the semiconductor IC dies 105 may include a solder material, such as tin or a tin-containing alloy, on the lower surface of the semiconductor die bonding structures 119. The semiconductor die bonding structures 119 on the lower surfaces of each semiconductor IC die 105 may be configured for microbump bonding (i.e., C2 bonding) to corresponding interposer bonding structures 106 on the first side surface 102 of the interposer 103.

The semiconductor IC dies 105 may be mounted over the first side surface 102 of the interposer 103 by placing each of the semiconductor IC dies 105 over the first side surface 102 of the interposer 103 (e.g., using a pick-and-place apparatus). The semiconductor IC dies 105 may be aligned over the first side surface 102 of the interposer 103 such that the semiconductor die bonding structures 119 on the lower surfaces of the semiconductor IC dies 105 contact corresponding interposer bonding structures 106 over the first side surface 102 of the interposer 103. A reflow process may be used to bond the semiconductor die bonding structures 119 on the lower surfaces of the semiconductor IC dies 105 to the corresponding interposer bonding structures 106 over the first side surface 102 of the interposer 103, thereby providing a mechanical and electrical connection between each of the semiconductor IC dies 105 and the interposer 103. In various embodiments, a plurality of semiconductor IC dies 105 may mounted over the first side surface 102 of the interposer 103 within each unit area (UA) of the first carrier substrate 101.

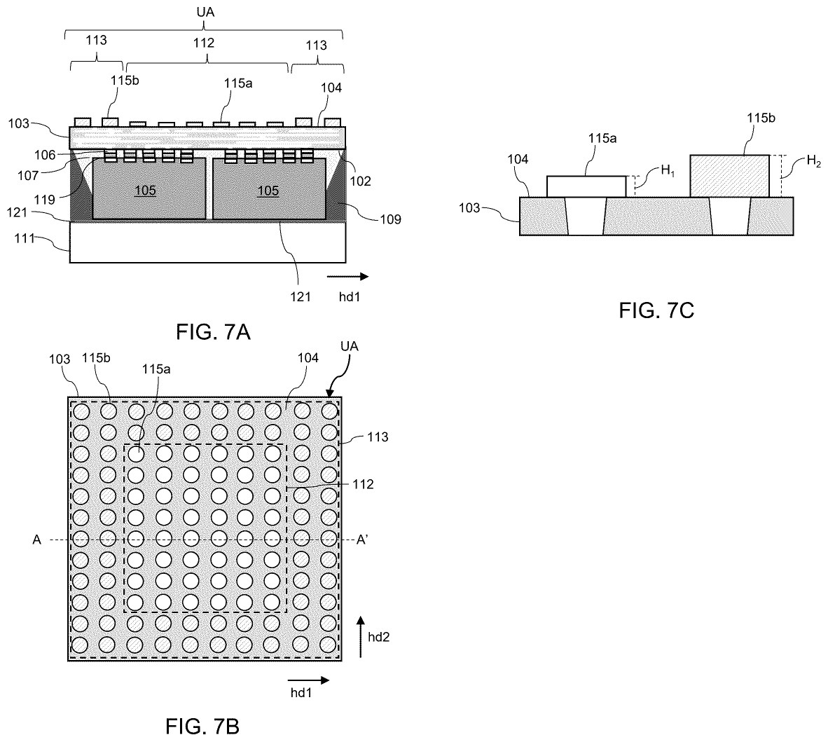

FIG. 4 is a vertical cross-section view of the exemplary intermediate structure showing a first underfill material portion 107 located between the lower surfaces of the semiconductor IC dies 105 and the first side surface 102 of the interposer 103, and a molding portion 109 around the outer periphery of the plurality of semiconductor IC dies 105 according to various embodiments of the present disclosure. Referring to FIG. 4, the first underfill material portion 107 may be applied into the spaces between the first side surface 102 of the interposer 103 and the plurality of semiconductor IC dies 105 mounted to the interposer 103. The first underfill material portion 107 may laterally surround and contact each of the interposer bonding structures 106 and semiconductor die bonding structures 119 that bond the respective semiconductor IC dies 105 to the interposer 103. The first underfill material portion 107 may also be located between adjacent semiconductor IC dies 105 of the plurality of semiconductor IC dies 105 mounted to the interposer 103.

The first underfill material portion 107 may include any underfill material known in the art. For example, the first underfill material portion 107 may be composed of an epoxy-based material, which may include a composite of resin and filler materials. Other suitable materials for the first underfill material portion 107 are within the contemplated scope of disclosure. Any known underfill material application method may be used to apply the first underfill material portion 107.

Referring again to FIG. 4, a molding portion 109 may laterally surround the plurality of semiconductor IC dies 105 mounted to the interposer 103. The molding portion 109 may contact lateral side surfaces of at least some of the semiconductor IC dies 105 and may also contact the first underfill material portion 107. In various embodiments, the molding portion 109 may include an epoxy material. For example, the molding portion 109 may include an epoxy mold compound (EMC) that may include epoxy resin, a hardener (i.e., a curing agent), silica or other filler material(s), and optionally additional additives. The EMC may be applied around the periphery of the semiconductor IC dies 105 in liquid or solid form, and may be hardened (i.e., cured) to form a molding portion 109 having sufficient stiffness and mechanical strength surrounding the plurality of semiconductor IC dies 105. Portions of the molding portion 109 that extend above a horizontal plane including the top surfaces of the semiconductor IC dies 105 may be removed using a planarization process, such as a chemical mechanical planarization (CMP) process.

In various embodiments, each unit area (UA) of the first carrier substrate 101 may include a first underfill material portion 107 located between the first side surface 102 of the interposer 103 and the undersides of the plurality of semiconductor IC dies 105 mounted to the interposer 103, and a molding portion 109 around the outer periphery of the plurality of semiconductor IC dies 105. In some embodiments, the molding portion 109 may form a continuous matrix extending between the unit areas (UAs) of the first carrier substrate 101 and laterally surrounding and embedding the respective sets of semiconductor IC dies 105 within each of the unit areas (UAs) of the first carrier substrate 101.

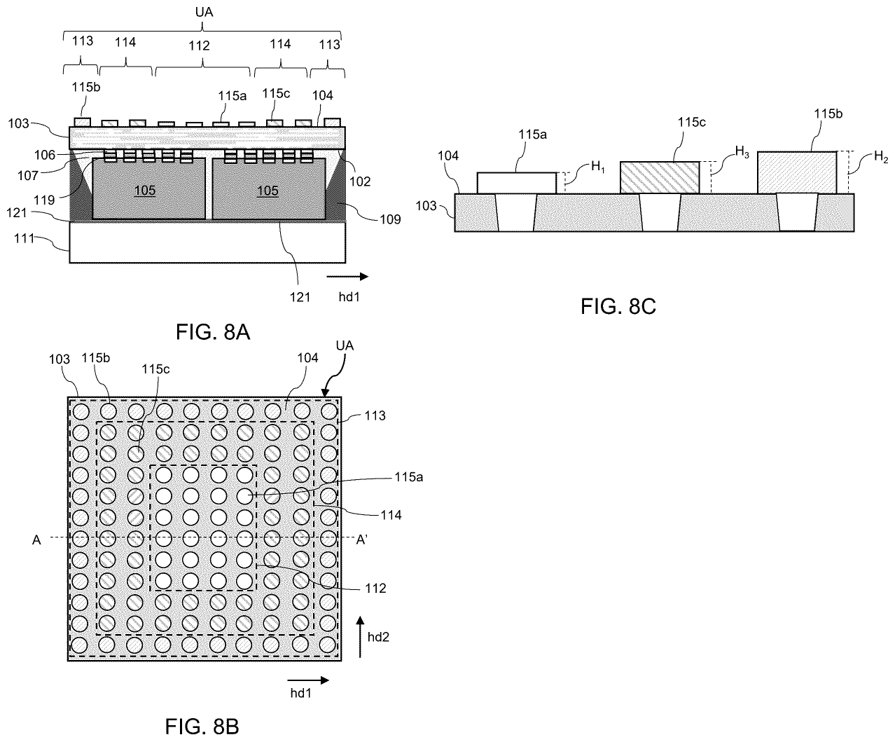

FIG. 5 is a vertical cross-section view of the exemplary intermediate structure showing a second release layer 121 located over the upper surfaces of the plurality of semiconductor dies 105, the exposed upper surface of the first underfill material portion 107 and the exposed upper surface of the molding portion 109, and a second carrier substrate 111 over the second release layer 121 according to various embodiments of the present disclosure. Referring to FIG. 5, the second release layer 121 may include an adhesive material that may adhere the second carrier substrate 111 to the upper surfaces of the plurality of semiconductor dies 105, the first underfill material portion 107 and the molding portion 109. As with the first release layer 117 described above, the second release layer 121 may also be configured to lose its adhesive properties when subjected to a treatment using an energy source, such as a thermal, optical (e.g., UV, laser, etc.) and/or sonic (e.g., ultrasonic) energy source. In some embodiments, the first release layer 117 and the second release layer 121 may be composed of the same material(s). Alternatively, the first release layer 117 and the second release layer 121 may be composed of different material(s).

Referring again to FIG. 5, the second carrier substrate 111 may be formed of a suitable substrate material, such as the materials described above with reference to the first carrier substrate 101 shown in FIG. 1. In some embodiments, the second carrier substrate 111 may be composed of the same material(s) as the first carrier substrate 101. Alternatively, the second carrier substrate 111 and the first carrier substrate 101 may be composed of different material(s). In various embodiments, the second carrier substrate 111 may extend over each of the unit areas (UAs) of the first carrier substrate 101 such that each unit area (UA) of the first carrier substrate 101 may correspond to an equivalent unit area (UA) of the second carrier substrate 111.

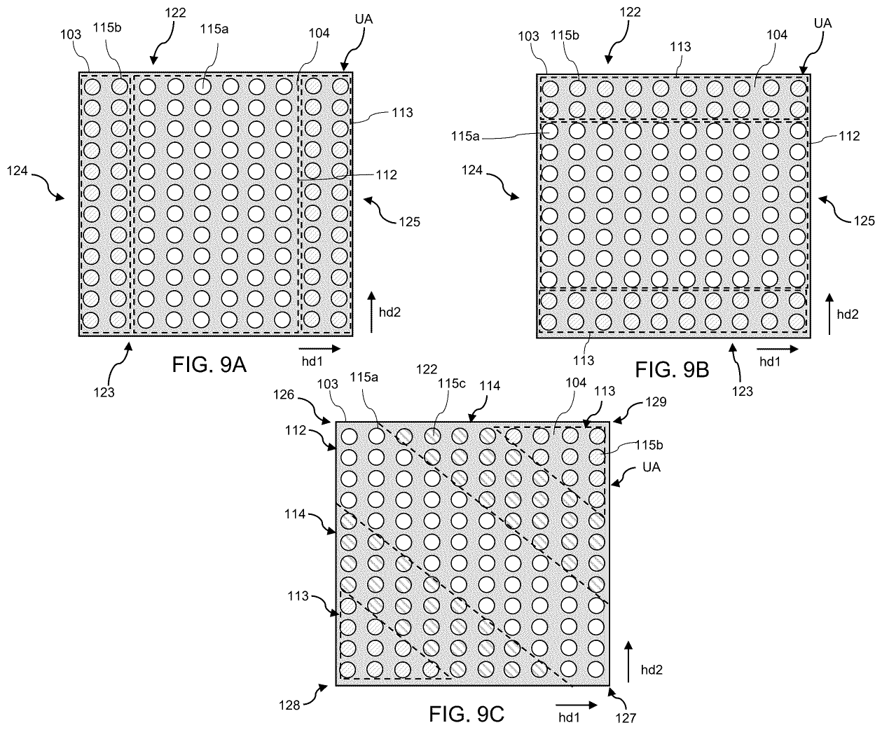

FIG. 6 is a vertical cross-section view of the exemplary intermediate structure showing the first carrier substrate 101 removed according to various embodiments of the present disclosure. Referring to FIG. 6, the first carrier substrate 101 may be removed using any suitable method known in the art. In embodiments in which the first carrier substrate 101 is adhered to the interposer 103 by a first release layer 117, the first release layer 117 may be subjected to a treatment that causes the first release layer 117 to lose its adhesive properties. This may enable the first carrier substrate 101 to be separated from the exemplary intermediate structure. For example, the first release layer 117 may include a light-to-heat conversion (LTHC) material that may be irradiated by optical radiation in a specified wavelength range, such as ultraviolet radiation, causing the LTHC material to heat up and thereby lose adhesion. The first release layer 117 may optionally be irradiated through the first carrier substrate 101 in embodiments in which the first carrier substrate 101 is composed of an optically-transparent material. Alternatively, the first release layer 117 may include a thermally-decomposing adhesive material. The exemplary intermediate structure be subjected to a thermal anneal process at a debonding temperature sufficient to cause the first release layer 117 to decompose and thereby enable the first carrier substrate 101 to be detached from the exemplary intermediate structure. In embodiments in which a thermal anneal process is used to remove the first carrier substate 101, the debonding temperature used to thermally decompose the first release layer 117 may not be sufficient cause the second release layer 121 to lose its adhesive properties.

Referring again to FIG. 6, the exemplary intermediate structure may be inverted (i.e., flipped over), either prior to or following the removal of the first carrier substrate 101, such that the interposer 103 may be located over and supported by the second carrier substrate 111.

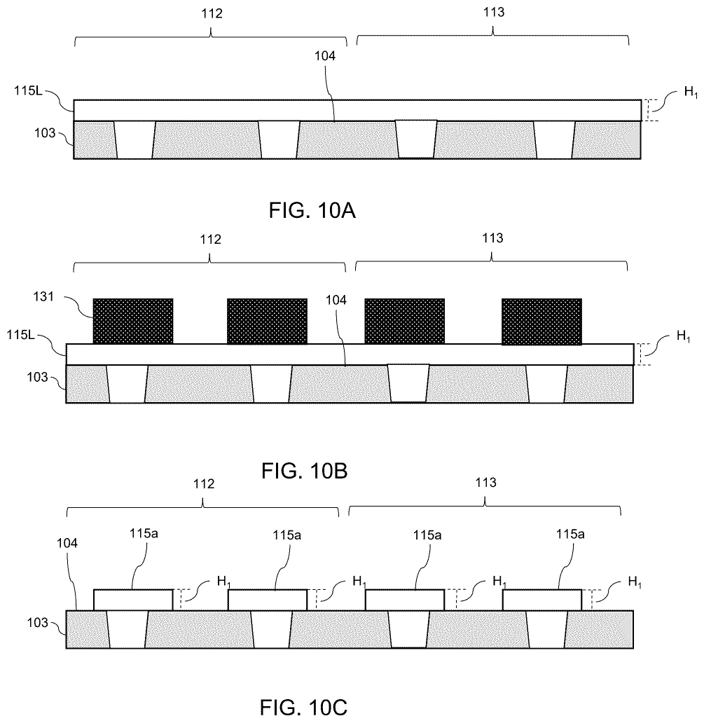

FIG. 7A is a vertical cross-section view of the exemplary intermediate structure showing a plurality of pillars 115a, 115b having different height dimensions located over the second side surface 104 of the interposer 103 according to various embodiments of the present disclosure. FIG. 7B is a top view of the exemplary intermediate structure of FIG. 7A. The vertical cross-section view of the exemplary intermediate structure of FIG. 7A is taken along line A-A′ in FIG. 7B. FIG. 7C is an enlarged vertical cross-section view illustrating a pair of pillars 115a and 115b having different height dimensions.

Referring to FIGS. 7A and 7B, the pillars 115a, 115b may be formed of a suitable metallic material, such as copper, aluminum, nickel, titanium, etc., including combinations and alloys thereof. Other suitable metallic materials for the bonding pads 115 are within the contemplated scope of disclosure. The pillars 115a, 115b may be a single layer structure, or may be a multi-layer structure composed of multiple layers of different metallic materials. Each of the pillars 115a, 115b may be electrically coupled to an underlying conductive interconnect structure 108 of the interposer 103. The pillars 115a, 115b may have a circular horizontal cross-sectional shape as shown in FIG. 7B. Other suitable horizontal cross-sectional shapes of the pillars 115a, 115b such as polygonal (e.g., rectangular or square), elliptical, and/or irregular shapes, are within the contemplated scope of disclosure. In some embodiments, the plurality of pillars 115a, 115b may form a periodic two-dimensional array (such as a rectangular array) of pillars 115a, 115b within the unit area (UA).

In various embodiments, the height dimensions of the pillars 115a, 115b may between about 5 μm and about 70 μm with respect to the second side surface 104 of the interposer 103, although greater and lesser height dimensions for the pillars 115a, 115b are within the contemplated scope of disclosure. The height dimensions of the pillars 115a, 115b may be non-uniform, meaning that a first set of one or more pillars 115a located in a first region 112 of the interposer 103 may have a height dimension that is different from the height dimension of a second set of one or more pillars 115b located in a second region 113 of the interposer 103. FIG. 7C illustrates the height dimension H₁ of a first pillar 115a that is less than the height dimension H₂ of a second pillar 115b. The interposer 103 may include at least two different regions, such as regions 112 and 113 shown in FIGS. 7A and 7B, where the height dimensions H₁ of the pillars 115a in a first region 112 of the interposer 103 may be different than the height dimensions H₂ of the pillars 115b in a second region 113 of the interposer 103.

In various embodiments, the variation in the height dimensions of the pillars 115a, 115b in different regions of the interposer 103 may be configured to compensate for a deformation of the interposer 103, such as a warping of the interposer 103, when the interposer 103 is mounted to a package substrate to form a semiconductor package. In some semiconductor packages that include an organic interposer 103 such as shown in FIGS. 7A-7C, the interposer 103 may have a tendency to deform (e.g., warp) around the periphery of the interposer 103, such that a separation or gap between the second side surface 104 of the interposer 103 and the surface of the package substrate to which the interposer is mounted may be relatively larger around the periphery of the interposer 103 and may decrease towards the center of the interposer. Accordingly, in the exemplary embodiment shown in FIGS. 7A and 7B, a height dimension H₂ of the pillars 115b in a peripheral region 113 of the interposer 103 may be greater than a height dimension H₁ of the pillars 115a in a central region 112 of the interposer 103. In some embodiments, the central region 112 of the interposer 103 may overlap a central point of the interposer 103.

Other configurations for the relative height dimensions of the pillars 115a, 115b may be utilized. For example, in embodiments in which the interposer 103 has a tendency to deform in a bow- or cup-shape such that the separation or gap between the second side surface 104 of the interposer 103 and the surface of the package substrate is greatest in the central region 112 of the interposer 103 and decreases towards the periphery of the interposer 103, the height dimension of the pillars in the central region 112 of the interposer 103 may be greater than the height dimension of the pillars in the peripheral region 113 of the interposer 103.

In various embodiments, a ratio of the height dimension (e.g., H₁) of the pillars 115a having the shortest height dimension in the interposer 103 to the height dimension (e.g., H₂) of the pillars 115b having the greatest height dimension in the interposer 103 may be between 0.03 and 1.0, such as between 0.07 and 0.98, including between 0.07 and 0.9 (e.g., between 0.07 and 0.85).

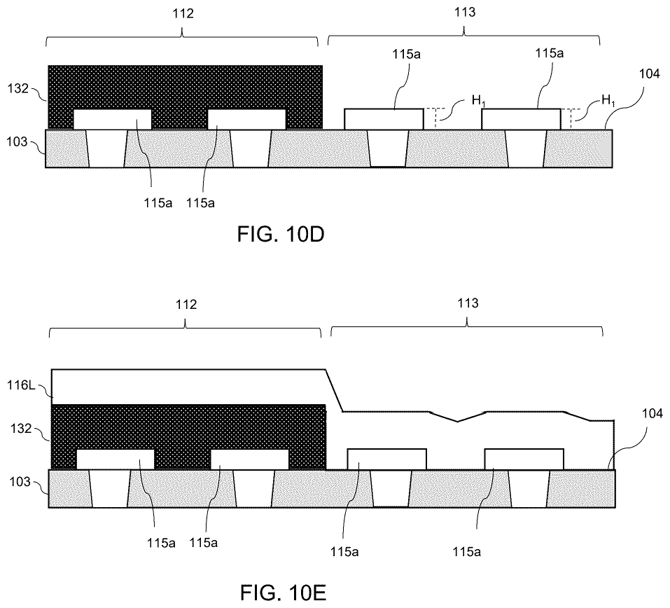

FIGS. 8A-8C illustrate an additional exemplary intermediate structure including a plurality of pillars 115a, 115b, 115c having three different height dimensions in different regions of the interposer 103 according to various embodiments of the present disclosure. FIG. 8A is a vertical cross-section view of the exemplary intermediate structure showing the plurality of pillars 115a, 115b, 115c located over the second side surface 104 of the interposer 103, and FIG. 8B is a top view of the exemplary intermediate structure of FIG. 8A. The vertical cross-section view of the exemplary intermediate structure of FIG. 8A is taken along line A-A′ in FIG. 8B. FIG. 8C is an enlarged vertical cross-section view illustrating pillars 115a, 115b, and 115C having height dimensions, H₁, H₂, and H₃, respectively.

Referring to FIGS. 8A-8C, the pillars 115a having the smallest height dimension H₁ may be located in a first region 112 of the interposer 103. In the exemplary embodiment shown in FIG. 8A-8C, the first region 112 corresponds to a central region of the interposer 103, although it will be understood that the pillars 115a having the smallest height dimension H₁ may be located in other region(s) of the interposer 103. The pillars 115b having the largest height dimension H₂ may be located in a second region 113 of the interposer 103. In the exemplary embodiment shown in FIG. 8A-8C, the second region 113 corresponds to a peripheral region of the interposer 103, although it will be understood that the pillars 115b having the largest height dimension H₂ may be located in other region(s) of the interposer 103. A third group of pillars 115c has an intermediate height dimension H₃ that is greater than the height dimension H₁ of pillars 115a and less than the height dimension H₂ of pillars 115b. The third group of pillars 115c may be located in a third region 114 of the interposer 103. In the exemplary embodiment shown in FIG. 8A-8C, the third region 114 of the interposer 103 is an intermediate region that is located between the first (i.e., central) region 112 and the second (i.e., peripheral) region 113 of the interposer 103, such that the third region 114 surrounds the first region 112 and the second region 113 surrounds the first region 112, although it will be understood that the pillars 115c having an intermediate height dimension H₃ may be located in other region(s) of the interposer 103. Further, although the exemplary embodiment of FIG. 8A-8C illustrates pillars 115a, 115b and 115c having three different height dimensions H₁, H₂, and H₃, respectively, it will be understood that the pillars may have more than three different height dimensions. For example, multiple groups of pillars having different intermediate height dimensions between height dimension H₁ and height dimension H₂ may be formed over the second side surface 104 of the interposer 103 such that the heights of the pillars may gradually increase or decrease between a central region and a peripheral region of the interposer 103.

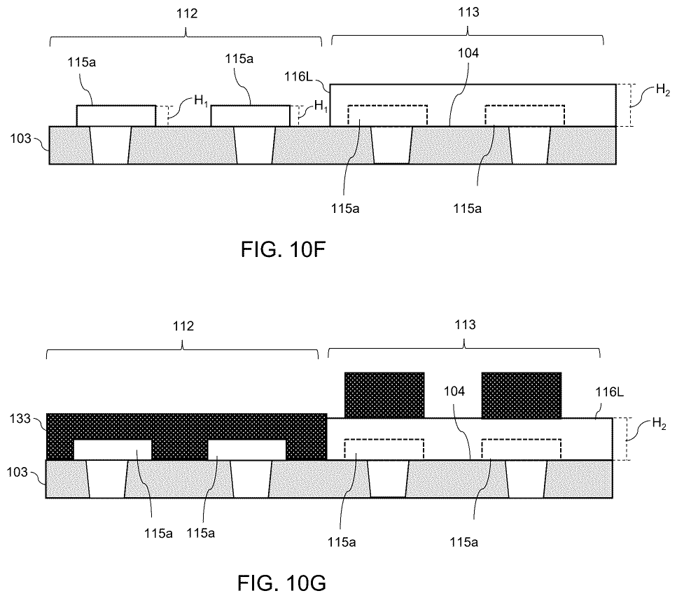

FIG. 9A is a top view of an exemplary intermediate structure according to yet another embodiment of the present disclosure illustrating an alternative arrangement of pillars 115a and 115b having non-uniform height dimensions. In the exemplary embodiment of FIG. 9A, adjacent pillars 115a, 115b along one horizontal direction (i.e., hd2) all share the same height dimension. However, along the orthogonal horizontal direction (i.e., hd1) the pillars 115a within a central region 112 of the interposer 103 have a first height dimension while pillars 115b in peripheral regions 113 of the interposer have a second height dimension that is different than the first height dimension. In some embodiments, the semiconductor IC dies 105 may be mounted over the first side surface 102 of the interposer 103 such that the semiconductor IC dies 105 may extend to or near first and second peripheral edges 122 and 123 on opposite sides of the interposer 103, and there may a relatively lower density of semiconductor IC dies 105, including no semiconductor IC dies 105 proximate to third peripheral edge 124 and fourth peripheral edge 125 on opposite sides of the interposer 103. This may result in a tendency for the interposer 103 to deform (e.g., warp) near the third peripheral edge 124 and fourth peripheral edge 125 of the interposer 103, such that a separation or gap between the second side surface 104 of the interposer 103 and the surface of the package substrate to which the interposer is mounted may be relatively larger near the third peripheral edge 124 and fourth peripheral edge 125 of the interposer 103 and may decrease towards the center of the interposer 103 along the first horizontal direction hd1. Accordingly, in some embodiments, the pillars 115b in peripheral regions 113 of the interposer 103 near the third peripheral edge 124 and fourth peripheral edge 125 may have a second height dimension that is greater than the first height dimension of the pillars 115a in the central region 112 of the interposer 103 in order to compensate for this deformation (i.e., warping) of the interposer 103 near the third peripheral edge 124 and fourth peripheral edge 125 of the interposer 103.

FIG. 9B is a top view of exemplary intermediate structure according to yet another embodiment of the present disclosure. The exemplary intermediate structure of FIG. 9B is similar to the exemplary intermediate structure of FIG. 9A, except that in the case of FIG. 9B, the pillars 115a, 115b along horizontal direction hd1 all share the same height dimension, while along horizontal direction hd2, the pillars 115b in peripheral regions 113 of the interposer 103 have a different height dimension than the pillars 115b in the central region 112 of the interposer 103. In some embodiments, the semiconductor IC dies 105 may be mounted over the first side surface 102 of the interposer 103 such that the semiconductor IC dies 105 may extend to or near the third peripheral edge 124 and fourth peripheral edge 125 on opposite sides of the interposer 103, and there may be a relatively lower density of semiconductor IC dies 105, including no semiconductor IC dies 105, proximate to first peripheral edge 122 and second peripheral edge 123 of the interposer 103. This may result in a tendency for the interposer 103 to deform (e.g., warp) near the first peripheral edge 122 and second peripheral edge 123 of the interposer 103, such that a separation or gap between the second side surface 104 of the interposer 103 and the surface of the package substrate to which the interposer is mounted may be relatively larger near the third peripheral edge 124 and fourth peripheral edge 125 of the interposer 103 and may decrease towards the center of the interposer 103 along the second horizontal direction hd2. Accordingly, in some embodiments, the pillars 115b in peripheral regions 113 of the interposer 103 near the first and second peripheral edges 122 and 123 may have a second height dimension that is greater than the first height dimension of the pillars 115a in the central region 112 of the interposer 103 in order to compensate for this deformation (i.e., warping) of the interposer 103 near the first peripheral edge 122 and second peripheral edge 123 of the interposer 103.

FIG. 9C is a top view of an exemplary intermediate structure according to yet another embodiment of the present disclosure illustrating an alternative arrangement of pillars 115a, 115b and 115c having non-uniform height dimensions. In this embodiment, a first region 112 of the interposer 103 including pillars 115a having a first height dimension extends from a first corner 126 of the interposer 103 (top left corner in FIG. 9C) along a diagonal direction through the central region of the interposer 103 to the opposite corner 127 of the interposer 103 (bottom right corner in FIG. 9C). A pair of second regions 113 of the interposer 113 including pillars 115b having a second height dimension are located proximate to the two other corners 128 and 129 of the interposer 103 (bottom left and top right corners in FIG. 9C). A pair of third regions 114 of the interposer 103 including pillars 115c having a third height dimension are extend along a diagonal direction between the first region 112 and the respective second regions 113. In some embodiments, the semiconductor IC dies 105 may be mounted over the first side surface 102 of the interposer 103 such that the semiconductor IC dies 105 may extend to or near a first corner 126 of the interposer 103 (top left corner in FIG. 9C) along a diagonal direction through the central region of the interposer 103 and to or near the opposite corner 127 of the interposer 103 (bottom right corner in FIG. 9C). There may be no semiconductor IC dies 105 proximate to third and fourth corners 128 and 129 of the interposer 103. This may result in a tendency for the interposer 103 to deform (e.g., warp) near the third and fourth corners 128 and 129 of the interposer 103, such that a separation or gap between the second side surface 104 of the interposer 103 and the surface of the package substrate to which the interposer is mounted may be relatively larger near the third and fourth corners 128 and 129 of the interposer 103 and may decrease towards the center of the interposer 103 and near the first and second corners 126 and 127. Accordingly, in order to compensate for this deformation (i.e., warping) of the interposer 103 near the third and fourth corners 127 and 128 of the interposer 103, the pillars 115a in the first region 112 extending diagonally between the first and second corners 126 and 127 of the interposer 103 may have a height dimension that is less than the height dimension of the pillars 115b in the pair of second regions 113 near the third and fourth corners 127 and 128 of the interposer 103. The height dimension of the pillars 115c in the third regions 114 located between the first region 112 and each of the second regions 113 may have an intermediate height dimension that is greater than the first height dimension and less than the second height dimension.

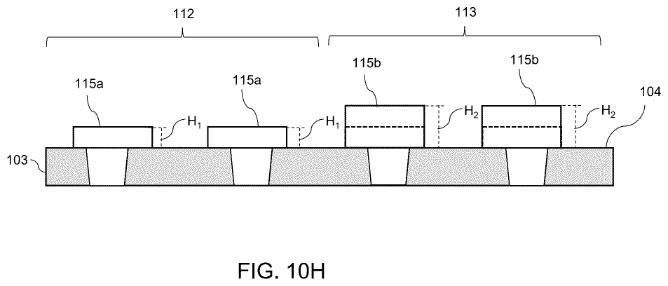

FIGS. 10A-10G are sequential vertical cross-section views illustrating an exemplary process of forming pillars 115a, 115b having different height dimensions over the second side surface 104 of the interposer 103 according to various embodiments of the present disclosure. Referring to FIG. 10A, a first continuous metallic material layer 115L may be deposited over the second side surface 104 of the interposer 103 using a suitable deposition method as described above. An optional planarization process, such as a chemical-mechanical planarization (CMP) process may be used to provide a planar upper surface of the first continuous metallic material layer 115L. The upper surface of the first continuous metallic material layer 115L may be above the second side surface 104 of the interposer 103 by a height dimension H₁. In various embodiments, the first continuous metallic material layer 115L may extend continuously over the second side surface 104 of the interposer 103, including over a first region 112 and a second region 113 of the interposer 103.

Referring to FIG. 10B, a patterned mask 131 may be formed over the upper surface of the first continuous metallic material layer 115L. In various embodiments, the patterned mask 131 may be formed by depositing a photoresist material over the upper surface of the first continuous metallic material layer 115L and lithographically patterning the photoresist material to form the patterned mask 131. For example, the photoresist material may be exposed to radiation through an optical mask to transfer the optical mask pattern to the photoresist material. The photoresist material may then be developed to remove select portions of the photoresist material and provide a patterned mask 131 as shown in FIG. 10B. The portions of the first continuous metallic material layer 115L that are covered by the patterned mask 131 may correspond to the locations of pillars 115a and 115b to be subsequently formed.

Referring to FIG. 10C, an etching process may be used to remove portions of the first continuous metallic material layer 115L and provide a plurality discrete pillars 115a over the second side surface 104 of the interposer 103. Each of the pillars 115a may have a uniform height dimension H₁. Following the etching process, the patterned mask 131 may be removed using a suitable process, such as via ashing or by dissolution using a solvent.

Referring to FIG. 10D, a patterned mask 132 may be formed over the pillars 115a and the second side surface 104 of the interposer 103 in the first region 112 of the interposer 103. The second region 113 of the interposer 103 may be exposed through the patterned mask 132. The patterned mask 132 may be formed using a lithographic process such as described above with reference to FIG. 10B.

Referring to FIG. 10E, a second continuous metallic material layer 116L may be deposited over the patterned mask 132 in the first region 112 of the interposer 103 and over the upper surfaces and side surfaces of the pillars 115a and the exposed second side surface 104 of the interposer 103 in the second region 113 of the interposer 103. The second continuous metallic material layer 116L may be deposited using a suitable deposition method as described above.

Referring to FIG. 10F, the second continuous metallic layer 116L and the patterned mask 132 may be removed from the first region 112 of the interposer 103. The second continuous metallic layer 116L may be removed from the first region 112 of the interposer 103 using any suitable method, such as via chemical-mechanical planarization (CMP) and/or an etching process. The patterned mask 132 may be removed via a suitable process, such as via ashing or dissolution using a solvent. An optional planarization process, such as a CMP process, may be used to provide a planar upper surface of the second continuous metallic layer 116L in the second region 113 of the interposer 103. The remaining portion of the second continuous metallic layer 116L in the second region 113 of the interposer 103 may have a height dimension H₂ that is greater than the height dimension H₁ of the pillars 115a in the first region 112 of the interposer 103.

Referring to FIG. 10G, a patterned mask 133 may be formed over the first region 112 of the interposer 103 and over the upper surface of the second continuous metallic layer 116L in the second region 113 of the interposer 103. The patterned mask 133 may be formed using a lithographic process such as described above with reference to FIG. 10B. The portions of the second continuous metallic material layer 116L that are covered by the patterned mask 133 may correspond to the locations of pillars 115b to be subsequently formed in the second region 113 of the interposer.

Referring to FIG. 10H, an etching process may be used to remove portions of the second continuous metallic material layer 116L and provide a plurality discrete pillars 115b over the second side surface 104 of the interposer 103 in the second region 113 of the interposer 103. Each of the pillars 115b may have a uniform height dimension H₂. The height dimension H₂ of the pillars 115b in the second region 113 may be greater than the height dimension H₁ of the pillars 115a in the first region 112. Following the etching process, the patterned mask 133 may be removed using a suitable process, such as via ashing or by dissolution using a solvent.

FIGS. 10A-10H illustrate a process of forming pillars 115a and 115b having two different height dimensions, H₁ and H₂. However, it will be understood that a process as shown and described above may be used to form pillars having more than two different height dimensions. For example, a mask may be formed over the pillars 115a in the first region 112 and a subset of the pillars 115b in the second region 113. An additional layer of metallic material may be deposited over the remaining pillars 115b that are exposed through the mask, and a patterning and etching process as shown in FIGS. 10G and 10H may be performed to form discrete pillars having a height dimension that is greater than height dimensions H₁ and H₂. This process may be repeated by adding additional metallic material to different subsets of the pillars to provide a pillar array including pillars having any number of different height dimensions.

Further, although FIGS. 10A-10H illustrate an exemplary process for forming pillars 115a, 115b having different height dimensions, it will be understood that other processes may be used to form the pillars 115a, 115b. For example, instead of an additive process as shown in FIGS. 10A-10H, a subtractive process may be used in which a group of pillars may be formed with an initial height dimension, and metallic material may be removed from some of the pillars of the group (e.g., via CMP and/or an etching process) to provide pillars having varying height dimensions.

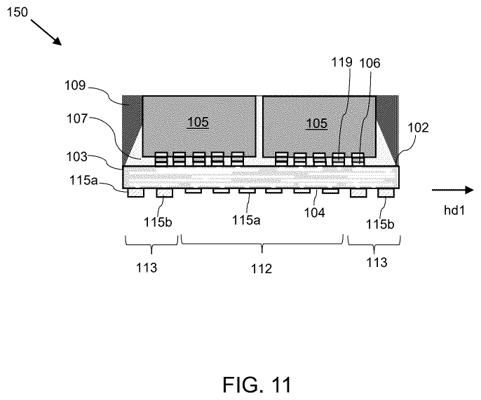

FIG. 11 is a vertical cross-section view of an exemplary intermediate structure showing a package structure 150 according to various embodiments of the present disclosure. Referring to FIG. 11, the second carrier substrate 111 may be removed from the exemplary intermediate package structure 150 shown in FIGS. 7A and 7B. The second carrier substrate 111 may be removed using any suitable method known in the art, such as any of the methods described above for removal of the first carrier substrate 101. In embodiments in which the second carrier substrate 111 is adhered to the semiconductor IC dies 105, the first underfill material portion 107 and the molding portion 109 using a second release layer 121, the second release layer 121 may be subjected to a treatment that causes the second release layer 121 to lose its adhesive properties, such as a thermal anneal and/or an optical irradiation treatment process as described above with reference to FIG. 6. The package structure 150 may be inverted relative to the orientation shown in FIGS. 7A and 7B.

A dicing process may be used to separate each unit area (UA) of the exemplary intermediate structure to provide a plurality of discrete package structures 150. Each package structure 150 may include an interposer 103, a plurality of semiconductor IC dies 105 mounted over a first side surface 102 of the interposer 103, a first underfill material portion 107 located in the gaps between the first side surface 102 of the interposer 103 and each of the semiconductor IC dies 105, and a molding portion 109 laterally surrounding the plurality of semiconductor IC dies 105.

The interposer 103 may include a plurality of pillars 115a, 115b having variable height dimensions located over a second side surface 104 of the interposer 103. Pillars 115a located in a first region 112 of the interposer 103 each have a first height dimension, and pillars 115b located in a second region 113 of the interposer each have a second height dimension that is different than the first height dimension. In the embodiment shown in FIG. 11, the first region 112 of the interposer 103 is a central region of the interposer 103, and the second region 113 of the interposer 103 is a peripheral region of the interposer 103. The pillars 115b located in the second (i.e., peripheral) region 113 of the interposer 103 have a height dimension that is greater than the height dimension of the pillars 115a located in the first (i.e., central) region 112 of the interposer 103. It will be understood that various other configurations are possible, including embodiments where the pillars in a central region of the interposer 103 have a greater height dimension than those in a peripheral region of the interposer 103, embodiments in which the pillars have three or more different height dimensions, and so forth.

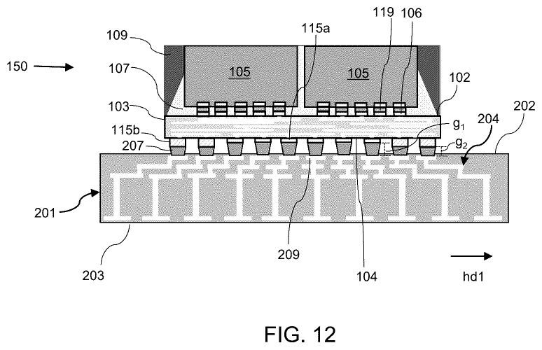

FIG. 12 is a vertical cross-section view of an exemplary intermediate structure during a process of forming a semiconductor package showing a package structure 150 mounted over the front side surface 202 of a package substrate 201 according to various embodiments of the present disclosure. Referring to FIG. 12, the package substrate 201 may include any suitable substrate material(s), such as polymer, glass, epoxy resin, ceramic and/or semiconductor substrate materials. The package substrate 201 may include a first side surface 202 (which, for convenience, may also be referred to as a “front” side surface 202 of the package substrate 201) and a second side surface 203 (which, for convenience, may also be referred to as a “rear” side surface 203 of the package substrate) that is opposite the first side surface 202.

In various embodiments, the package substrate 201 may include redistribution structures 204 (e.g., metal lines, vias, bonding regions, etc.) extending within the package substrate 201. In some embodiments, the rear side surface 203 of the package substrate 201 may be configured to be mounted to a supporting substrate, such as a printed circuit board (PCB). Electrical connections between the supporting substrate (e.g., a PCB) and the semiconductor package may be made via the redistribution structures 204 within the package substrate 201.

Referring again to FIG. 12, the package structure 150 may be aligned over the package substrate 201 such that the second side surface 104 of the interposer 103 faces the front side surface 202 of the package substrate 201. The package structure 150 may be disposed over the front side surface 202 of the package substrate 201 such that an array of solder material portions 207 are located between redistribution structures 204 (e.g., bonding pads 209) that are exposed through the front side surface 202 of the package substrate 201 and the pillars 115a, 115b over the second side surface 104 of the interposer 103.

A reflow process may be performed to reflow the solder material portions 207, thereby inducing bonding between the interposer 103 of the package structure 150 and the package substrate 201. Each of the solder material portions 207 may be bonded to a respective one of the pillars 115a, 115b over the second side surface 104 of the interposer 103 and to a respective one of redistribution structures 204 (e.g., bonding pads 209) of the package substrate 201. In some embodiments, the solder material portions 207 may include C4 solder balls, and the package structure 150 may be bonded to the substrate package 201 through an array of C4 solder balls.

In various embodiments, the differences in the height dimensions of the pillars 115a, 115b may provide a variation in the size of the gaps between the lower surfaces of the pillars 115a, 115b and the upper surfaces of the bonding pads 209 of the package substrate 201 to which the respective pillars 115a, 115b are bonded. As shown in the exemplary embodiment of FIG. 12, the gaps g₂ between the lower surfaces of the pillars 115b and the upper surfaces of the bonding pads 209 near the periphery of the interposer 103 are less than the gaps g₁ between the lower surfaces of the pillars 115a and the upper surfaces of the bonding pads 209 near the center of the interposer 103. This variation in gap size may help to compensate for a deformation (e.g., warping) of the interposer 103 in which the second side surface 104 of the interposer 103 pulls away from the front side surface 202 of the package substrate 201 around the periphery of the interposer 103. In instances in which the size of the gaps between the lower surfaces of the pillars 115a, 115b and the upper surfaces of the bonding pads 209 is uniform (e.g., all having gap size g₁), such a deformation around the periphery of the interposer 103 may increase the gap size around the periphery of the interposer 103, such that the gap size around the periphery of the interposer 103 may be significantly larger than g₁. In some cases, the gap sizes between the pillars and the bonding pads around the periphery of the interposer may extend beyond the effective “joint window” of the solder connections, resulting in solder connections that are subject to solder cold joints and other defects.

In the exemplary embodiment shown in FIG. 12, because the size of the gaps g₂ around the periphery of the interposer 103 is less than the size of the gaps g₁ in the center of the interposer 103, in instances in which the interposer 103 deforms (i.e., warps) such that the second side surface 104 of the interposer 103 pulls away from the front side surface 202 of the package substrate 201 around the periphery of the interposer 103, the size of the gaps g₂ around the periphery of the interposer 103 may not significantly exceed the size of the gaps g₁ in the central region of the interposer 103, and may remain within the effective “joint window” of the solder connections. This may improve the reliability of the electrical connections between the interposer 103 and the package substrate 201.

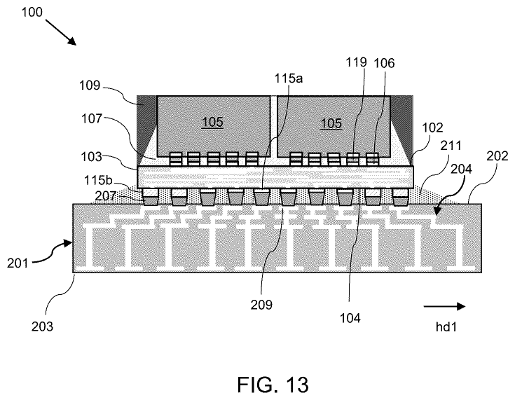

FIG. 13 is a vertical cross-section view of a semiconductor package 100 including a second underfill material portion 211 located between the front side surface 202 of the package substrate 201 and the second side surface 104 of the interposer 103 according to various embodiments of the present disclosure. Referring to FIG. 13, the second underfill material portion 211 may be applied into the space between the front side surface 202 of the package substrate 201 and the second side surface 104 of the interposer 103. The second underfill material portion 211 may laterally surround and contact each of the solder material portions 207 that bond the interposer 103 to the package substrate 201 and may also laterally surround and contact each of the pillars 115a, 115b.

The second underfill material portion 211 may include any underfill material known in the art. For example, the second underfill material portion 211 may be composed of an epoxy-based material, which may include a composite of resin and filler materials. Other suitable materials for the second underfill material portion 211 are within the contemplated scope of disclosure. Any known underfill material application method may be used to apply the second underfill material portion 211.

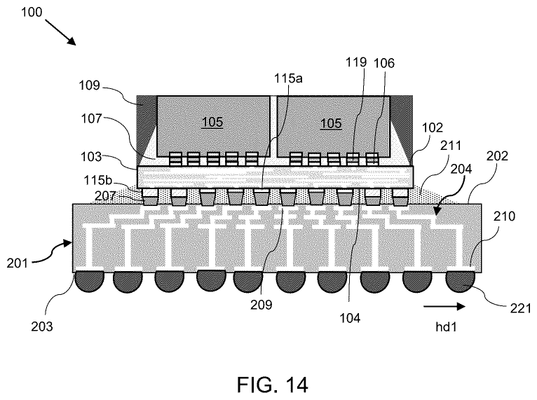

FIG. 14 is a vertical cross-section view of the semiconductor package 100 including a plurality of solder balls 221 located on the rear side surface 203 of the package substrate 201. Each of the solder balls 221 may contact bonding pads 210 exposed through the rear side surface 203 of the package substrate 201. The solder balls 221 may be used to mount the rear side surface 203 of the semiconductor package 200 onto a support substrate containing electrical interconnects, such as a printed circuit board (PCB). In some embodiments, the solder balls 221 may include a ball grid array (BGA), and the semiconductor package 100 may be mounted to the support substrate via a BGA connection.

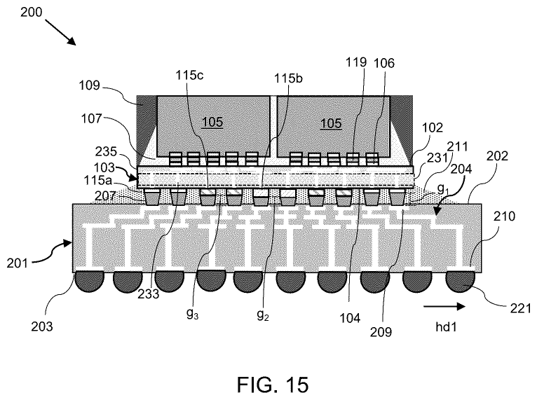

FIG. 15 is a vertical cross-section view of a semiconductor package 200 according to another embodiment of the present disclosure. Referring to FIG. 15, the semiconductor package 200 according to the alternative embodiment may be similar to the semiconductor package 100 shown in FIG. 14, and may include a package structure 150 having interposer 103, a plurality of semiconductor IC dies 105 mounted over a first side surface 102 of the interposer 103, a first underfill material portion 107 located in the gaps between the first side surface 102 of the interposer 103 and each of the semiconductor IC dies 105, and a molding portion 109 laterally surrounding the plurality of semiconductor IC dies 105.

The interposer 103 may include a plurality of pillars 115a, 115b and 115c having variable height dimensions located over a second side surface 104 of the interposer 103. The package structure 150 may be bonded to the front side surface 202 of a package substrate 201 via a plurality of solder material portions 207. A second underfill material portion 211 may be located in the space between the front side surface 202 of the package substrate 201 and the second side surface 104 of the interposer 103 and laterally surrounding the plurality of solder material portions 207 and the plurality of pillars 115a, 115b and 115c.

In the embodiment shown in FIG. 15, the interposer 103 is a semiconductor material interposer as opposed to an organic interposer. Referring to FIG. 15, the semiconductor material interposer 103 may include a semiconductor material member 231, such as a silicon member, having a plurality of conductive through-vias 233 (e.g., through-silicon vias) extending therethrough. The conductive through-vias 233 may carry electrical signals between the plurality of semiconductor IC dies 105 mounted to the first side surface 102 of the interposer 103 and the package substrate 201. In some embodiments, the semiconductor material interposer 103 may include at least one redistribution layer 235 including interconnect structures embedded in a dielectric material matrix located above and/or below the semiconductor material member 231.

In the embodiment shown in FIG. 15, the pillars 115a having the smallest height dimension are located near the periphery of the interposer 103, and the pillars 115b having the largest height dimension are located near the center of the interposer 103. In addition, pillars 115c having an intermediate height dimension that is greater than the height dimension of pillars 115a and less than the height dimension of pillars 115b are located between pillars 115a and pillars 115c on the interposer 103. The configuration of the pillars 115a, 115b and 115c as shown in FIG. 15 may compensate for a bow- or cup-shaped deformation (e.g., warping) of the interposer 103 away from the font side surface 202 of the package substrate 201. In such a case, the maximum separation between the second surface 104 of the interposer 103 and the front side surface 202 of the package substrate 201 typically occurs in the central region of the interposer 103, with a more moderate separation occurring in the intermediate region between the central region and the periphery of the interposer 103. This separation of the interposer 103 from the front side surface 202 of the package substrate 201 may result in defective solder connections, particularly in the central and intermediate regions of the interposer 103 where the magnitude of the deformation is greatest.

In the embodiment of FIG. 15, because the pillars 115b near the central region of the interposer 103 have a larger height dimension than the height dimension of the pillars 115a around the periphery of the interposer 103, the gap g₂ between the lower surfaces of pillars 115b and the upper surfaces of the bonding pads 209 in the central region of the interposer 103 is less than the gap g₁ between the lower surfaces of pillars 115a and the upper surfaces of the bonding pads 209 in the periphery of the interposer 103. In the intermediate region between the central region and peripheral region of the interposer 103, the pillars 115c have an intermediate height dimension that is less than the height dimension of pillars 115b and greater than the height dimension of pillars 115a, and thus the gap g₃ in the intermediate region is greater than gap g₂ and less than gap g₁. Thus, in the event that the interposer 103 undergoes a bow- or cup-shaped deformation (e.g., warping) away from the font side surface 202 of the package substrate 201, the size of the gaps g₂ and g₃ in the central and intermediate regions may increase with the deformation of the interposer 103, but may still not significantly exceed the size of the gaps g₁ in the central region of the interposer 103. Accordingly, defective solder connections may be minimized or avoided, and the reliability of the electrical connections between the interposer 103 and the package substrate 201 may be improved.

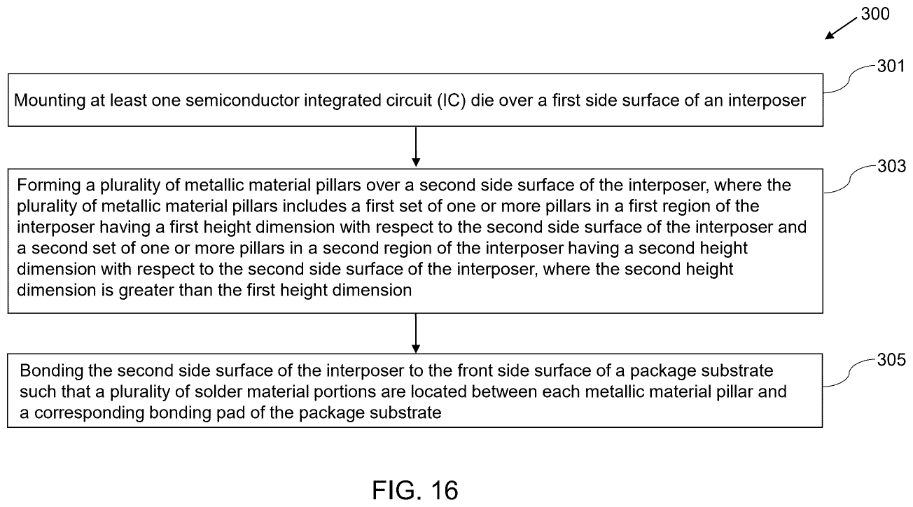

FIG. 16 is a flowchart illustrating a method 300 of fabricating a semiconductor package 100, 200 according to various embodiments of the present disclosure. Referring to FIGS. 1-3 and 16, in step 301 of embodiment method 300, at least one semiconductor integrated circuit (IC) die 105 may be mounted over a first side surface 102 of an interposer 103. Referring to FIGS. 7A-10H and 16, in step 303 of embodiment method 300, a plurality of metallic material pillars 115a, 115b may be formed over a second side surface 104 of the interposer 103, where the plurality of metallic material pillars 115a, 115b, 115c includes a first set of one or more pillars 115a in a first region 112 of the interposer having a first height dimension H₁ with respect to the second side surface 104 of the interposer 103, and a second set of one or more pillars 115b in a second region 113 of the interposer 103 having a second height dimension H₂ with respect to the second side surface 104 of the interposer 103, where the second height dimension H₂ is greater than the first height dimension H₁. In some embodiments, the first region 112 may be a central region of the interposer 103 and the second region 113 may be a peripheral region of the interposer 103. In other embodiments, the first region 112 may be a peripheral region of the interposer 103 and the second region 113 may be a central region of the interposer 103

In some embodiments, step 303 of embodiment method 300 may further include forming the plurality of metallic material pillars 115a, 115b, 115c to include a third set of one or more pillars 115c in a third region 114 of the interposer having a third height dimension H₃ with respect to the second side surface 104 of the interposer 103 that is greater than the first height dimension H₁ and less than the second height dimension H₂. In some embodiments, the third region 114 may be an intermediate region located between a central region and a peripheral region of the interposer 103.

Referring to FIGS. 12 and 16, in step 305 of embodiment method 300, the second side surface 104 of the interposer 103 may be bonded to the front side surface 202 of a package substrate 201 such that a plurality of solder material portions 207 are located between each metallic material pillar 115a, 115b and a corresponding bonding pad 209 of the package substrate 201.

Referring to all drawings and according to various embodiments of the present disclosure, a semiconductor package 100, 200 may include an interposer 103, at least one semiconductor integrated circuit (IC) die 105 mounted over a first surface 102 of the interposer 103, a plurality of metallic material pillars 115a, 115b over a second surface 104 of the interposer 103, where the plurality of metallic material pillars 115a, 115b includes a first set of one or more metallic material pillars 115a in a first region 112 of the interposer 103 having a first height dimension H₁ with respect to the second surface 104 of the interposer 103, and a second set of one or more metallic material pillars 115b in a second region 113 of the interposer 103 having a second height dimension H₂ with respect to the second surface 104 of the interposer 103, where the second height dimension H₂ is greater than the first height dimension H₁, a package substrate 201 including a plurality of bonding pads 209 on a front side surface 202 of the package substrate 201, and a plurality of solder material portions 207 located between respective metallic material pillars 115a, 115b over the second surface 104 of the interposer 103 and respective bonding pads 209 of the package substrate 201.

In an embodiment, the first region 112 of the interposer 103 overlaps a central point of the interposer 103 and the second region 113 of the interposer 103 surrounds the central region. In another embodiment, the second region 113 of the interposer 103 overlaps a central point of the interposer 103 and the first region 112 of the interposer 103 surrounds the second region. In another embodiment, the plurality of metallic material pillars 115a, 115b each have a height dimension that is at least 5 μm and equal to or less than 70 μm. In another embodiment, a ratio of the first height dimension H₁ of the first set of one or more metallic material pillars 115a in the first region 112 of the interposer 103 to the second height dimension H₂ of the second set of one or more metallic material pillars 115b in the second region 113 of the interposer 103 is between 0.07 and 0.98. In another embodiment, the plurality of metallic material pillars includes a third set of one or more metallic material pillars 115c in a third region 114 of the interposer 103 having a third height dimension H₃ with respect to the second surface 104 of the interposer 103, where the third height dimension H₃ is greater than the first height dimension H₁ and less than the second height dimension H₂. In another embodiment, the first region 112 of the interposer 103 overlaps a central point of the interposer 103, the third region 114 of the interposer 103 surrounds the first region 112 of the interposer 103, and the second region 113 of the interposer 103 surrounds the third region 114 of the interposer 103. In another embodiment, the first region 112 of the interposer 103 extends in a diagonal direction between a first corner 126 and a second corner 127 of the interposer 103, the interposer 103 includes a pair of second regions 113 adjacent to respective third and fourth corners 128 and 129 of the interposer 103, and the interposer 103 includes a pair of third regions 114, each third region 114 of the pair of third regions 114 located between the first region 112 of the interposer 103 and a respective second region 113 of the pair of second regions 113 of the interposer 103. In another embodiment, the first region 112 of the interposer 103 extends between first and second peripheral edges 122, 123, 124, 125 of the interposer 103 on opposite sides of the interposer 103 and overlaps a central point of the interposer 103, and the interposer comprises a pair of second regions 113 each extending between the first and second peripheral edges 122, 123, 124, 125 of the interposer 103, each second region 113 of the pair of second regions 113 located between the first region 112 of the interposer 103 and respective third and fourth peripheral edges 124, 125, 122, 123 on opposite sides of the interposer 103. In another embodiment, the second region 113 of the interposer 103 extends between first and second peripheral edges 122, 123, 124, 125 of the interposer 103 on opposite sides of the interposer 103 and overlaps a central point of the interposer 103, and the interposer comprises a pair of first regions 112 each extending between the first and second peripheral edges 122, 123, 124, 125 of the interposer 103, each first region 113 of the pair of first regions 113 located between the second region 112 of the interposer 103 and respective third and fourth peripheral edges 124, 125, 122, 123 on opposite sides of the interposer 103. In another embodiment, the interposer 103 includes an organic interposer 103 having interconnect structures 108 embedded in a dielectric polymer material matrix 118. In another embodiment, the interposer 103 includes a semiconductor material interposer having a plurality of conductive through-vias 233 extending through a semiconductor material member 221.

An additional embodiment is drawn to an interposer 103 for a semiconductor package 100, 200 that includes a first surface 102, a second surface 104, a plurality of redistribution structures 108 located between the first surface 102 and the second surface 104 of the interposer 103, and a plurality of metallic material pillars 115a, 115b over the second surface 104 of the interposer 103 and electrically contacting the plurality of redistribution structures 108, where the plurality of metallic material pillars 115a, 115b over the second surface 104 of the interposer 103 have non-uniform height dimensions.

In an embodiment, the plurality of metallic material pillars 115a, 115b include a periodic two-dimensional array of metallic material pillars 115a, 115b, where a first set of metallic material pillars 115a in a central region of the array has a first height dimension H₁, and a second set of metallic material pillars 115b in a peripheral region of the array has a second height dimension H₂ that is different than the first height dimension H₁. In another embodiment, the peripheral region of the array including metallic material pillars 115b having the second height dimension H₂ laterally surrounds the central region of the array on four sides. In another embodiment, the central region of the array including metallic material pillars 115a having the first height dimension H₁ extends in a diagonal a diagonal direction between first and second corners 126 and 127 of the array, and the array includes a pair of peripheral regions including metallic material pillars 115b having the second height dimension H₂, where each of the peripheral regions is located between the central region and respective third and fourth corners 128 and 129 of the array. In another embodiment, the array includes a first region of metallic material pillars 115a having a first height dimension H₁ that extends along a first direction hd1, hd2 between first and second peripheral edges 123, 124, 125, 126 of the array, and a pair of second regions having metallic material pillars 115b having a second height dimension H₂ that is different than the first height dimension H₁, each second region of the pair of second regions extending along the first direction hd1, hd2 between the first and second peripheral edges 123, 124, 125, 126 of the array, and each of the respective second regions is located between the central region and respective third and fourth peripheral edges 125, 126, 123, 124 of the array along a second direction hd2, hd1 that is orthogonal to the first direction hd1, hd2.

An additional embodiment is drawn to a method of fabricating a semiconductor package that includes mounting at least one semiconductor integrated circuit (IC) die 105 over a first surface 102 of an interposer 103, forming a plurality of metallic material pillars 115a, 115b over a second surface 104 of the interposer 103, where the plurality of metallic material pillars 115a, 115b includes a first set of one or more metallic material pillars 115a in a first region 112 of the interposer 103 having a first height dimension H₁ with respect to the second surface 104 of the interposer 104, and a second set of one or more metallic material pillars 115b in a second region 113 of the interposer 103 having a second height dimension H₂ with respect to the second surface 104 of the interposer 103, where the second height dimension H₂ is greater than the first height dimension H₁, and bonding the second surface 104 of the interposer 103 to a front surface 202 of a package substrate 201 such that a plurality of solder material portions 207 are located between each metallic material pillar 115a, 115b and a corresponding bonding pad 209 of the package substrate 201.

In an embodiment, forming the plurality of metallic material pillars 115a, 115b includes depositing a first continuous metallic material layer 115L over the second surface 104 of the interposer 103, patterning the continuous metallic material layer 115L to form a plurality of metallic material pillars 115a having the first height dimension H₁, forming a mask 134 over the metallic metal pillars 115a in the first region 112 of the interposer 103, where the metallic material pillars 115a in the second region 113 of the interposer are exposed through the mask 134, depositing a second continuous metallic material layer 116L over the metallic material pillars 115a in the second region 113 of the interposer 103, and patterning the second continuous metallic material layer 116L to form a plurality of metallic material pillars 115b having the second height dimension H₂ in the second region 113 of the interposer 103. In another embodiment, the method further includes forming the interposer 103 over a first carrier substrate 101, forming a plurality of interposer bonding structures 106 over the first surface 102 of the interposer 103, where a plurality of semiconductor IC dies 105 are mounted over the first surface 102 of the interposer 103 via the plurality of interposer bonding structures 106, providing a first underfill material portion 107 between the first surface 102 of the interposer and underside surfaces of the plurality of semiconductor IC dies 105 and between the respective semiconductor IC dies 105, forming a molding portion 109 laterally surrounding the plurality of semiconductor IC dies 105, providing a second carrier substrate 111 over upper surfaces of the plurality of semiconductor IC dies 105, the first underfill material portion 107 and the molding portion 109, removing the first carrier substrate 101 from the second surface 104 of the interposer 103, and removing the second carrier substrate 111 from over the upper surfaces of the plurality of semiconductor IC dies 105, the first underfill material portion 107 and the molding portion 109 after forming the metallic material pillars 115a, 115b over the second surface 104 of the interposer 103.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor package, comprising:
mounting at least one semiconductor integrated circuit (IC) die over a first surface of an interposer;
forming a plurality of metallic material pillars over a second surface of the interposer, wherein the plurality of metallic material pillars comprises a first set of one or more metallic material pillars in a first region of the interposer having a first height dimension with respect to the second surface of the interposer, and a second set of one or more metallic material pillars in a second region of the interposer having a second height dimension with respect to the second surface of the interposer, wherein the second height dimension is greater than the first height dimension; and
bonding the second surface of the interposer to a front surface of a package substrate such that a plurality of solder material portions are located between each metallic material pillar and a corresponding bonding pad of the package substrate.

2. The method of claim 1, wherein forming the plurality of metallic material pillars comprises:
depositing a first continuous metallic material layer over the second surface of the interposer;
patterning the first continuous metallic material layer to form the first set of one or more metallic material pillars having the first height dimension;
forming a mask over the first set of one or more metallic material pillars in the first region of the interposer, wherein the second set of one or more metallic material pillars in the second region of the interposer are exposed through the mask;
depositing a second continuous metallic material layer over the second set of one or more metallic material pillars in the second region of the interposer; and
patterning the second continuous metallic material layer to form the second set of one or more metallic material pillars having the second height dimension in the second region of the interposer.

3. The method of claim 1, further comprising:
forming the interposer over a first carrier substrate;
forming a plurality of interposer bonding structures over the first surface of the interposer, wherein a plurality of semiconductor IC dies are mounted over the first surface of the interposer via the plurality of semiconductor IC dies;
providing a first underfill material portion between the first surface of the interposer and underside surfaces of the plurality of semiconductor IC dies and between the respective semiconductor IC dies;
forming a molding portion laterally surrounding the plurality of semiconductor IC dies;
providing a second carrier substrate over upper surfaces of the plurality of semiconductor IC dies, the first underfill material portion and the molding portion;
removing the first carrier substrate from the second surface of the interposer; and
removing the second carrier substrate from over the upper surfaces of the plurality of semiconductor IC dies, the first underfill material portion and the molding portion after forming the plurality of metallic material pillars over the second surface of the interposer.

4. The method of claim 1, wherein forming the plurality of metallic material pillars comprises forming the first set of one or more metallic material pillars in the first region that overlaps a central point of the interposer and forming the second set of one or more metallic material pillars in the second region that surrounds the first region.

5. The method of claim 1, wherein forming the plurality of metallic material pillars comprises forming the second set of one or more metallic material pillars in the second region that overlaps a central point of the interposer and forming the first set of one or more metallic material pillars in the first region that surrounds the second region.

6. The method of claim 1, wherein forming the plurality of metallic material pillars comprises forming each of the metallic material pillars to have a height dimension that is at least 5 μm and equal to or less than 70 μm.

7. The method of claim 1, wherein forming the plurality of metallic material pillars comprises forming the first set of one or more metallic material pillars and the second set of one or more metallic material pillars such that a ratio of the first height dimension to the second height dimension is between 0.07 and 0.98.

8. The method of claim 1, wherein forming the plurality of metallic material pillars further comprises forming a third set of one or more metallic material pillars in a third region of the interposer having a third height dimension with respect to the second surface of the interposer, wherein the third height dimension is greater than the first height dimension and less than the second height dimension.

9. The method of claim 8, wherein the first region of the interposer overlaps a central point of the interposer, the third region of the interposer surrounds the first region of the interposer, and the second region of the interposer surrounds the third region of the interposer.

10. The method of claim 1, wherein the interposer comprises an organic interposer having interconnect structures embedded in a dielectric polymer material matrix.

11. A method for fabricating a semiconductor package, comprising:
placing at least one semiconductor integrated circuit (IC) die over a first surface of an interposer using a pick-and-place apparatus;
aligning the at least one semiconductor IC die over the first surface of the interposer such that semiconductor die bonding structures on a lower surface of the at least one semiconductor IC die contact corresponding interposer bonding structures over the first surface of the interposer;
performing a first reflow process to bond the semiconductor die bonding structures to the corresponding interposer bonding structures;
depositing a first continuous metallic material layer over a second surface of the interposer;
patterning the first continuous metallic material layer to provide a plurality of discrete pillars, wherein the plurality of discrete pillars comprises a first set of one or more metallic material pillars in a first region of the interposer having a first height dimension with respect to the second surface of the interposer, and a second set of one or more metallic material pillars in a second region of the interposer having a second height dimension with respect to the second surface of the interposer, wherein the second height dimension is greater than the first height dimension; and
performing a second reflow process to reflow solder material portions between the second surface of the interposer and a front surface of a package substrate, thereby inducing bonding between the interposer and the package substrate such that the solder material portions are located between each metallic material pillar and a corresponding bonding pad of the package substrate.

12. The method of claim 11, wherein patterning the first continuous metallic material layer comprises:
exposing a photoresist material to radiation through an optical mask to transfer an optical mask pattern to the photoresist material;
developing the photoresist material to remove select portions of the photoresist material and provide a patterned mask; and
etching portions of the first continuous metallic material layer using the patterned mask to provide the plurality of discrete pillars.

13. The method of claim 11, wherein placing the at least one semiconductor IC die comprises placing a plurality of semiconductor IC dies over the first surface of the interposer, and further comprising:
applying a first underfill material portion into spaces between the first surface of the interposer and the plurality of semiconductor IC dies; and
applying a molding portion around an outer periphery of the plurality of semiconductor IC dies using an epoxy mold compound.

14. The method of claim 11, wherein the at least one semiconductor IC die comprises at least one of a system-on-chip die, a central processing unit die, a graphic processing unit die, a high bandwidth memory die, or a dynamic random access memory die.

15. The method of claim 11, wherein performing the second reflow process to reflow the solder material portions comprises heating the solder material portions to a temperature sufficient to cause the solder material portions to melt and form electrical connections between the corresponding bonding pad of the package substrate and the first and second sets of one or more metallic material pillars.

16. A method for fabricating a semiconductor package, comprising:
sequentially depositing layers of a dielectric polymer material over a front side surface of a first carrier substrate;
patterning and etching each of the layers of the dielectric polymer material to form open regions;
filling the open regions with conductive material using a metallization process to form conductive interconnect structures within each successive layer of dielectric polymer material, thereby building an interposer layer-by-layer over the front side surface of the first carrier substrate;
applying at least one semiconductor integrated circuit die over a first surface of the interposer using a pick-and-place apparatus;
subjecting the interposer and the at least one semiconductor integrated circuit die to a first reflow process to bond semiconductor die bonding structures to corresponding interposer bonding structures;
sequentially depositing and patterning metallic material layers over a second surface of the interposer to provide a plurality of metallic material pillars having non-uniform height dimensions in different regions of the interposer; and
subjecting solder material portions to a second reflow process to electrically connect the plurality of metallic material pillars to corresponding bonding pads of a package substrate.

17. The method of claim 16, wherein sequentially depositing and patterning the metallic material layers comprises:
depositing a first metallic material layer over the second surface of the interposer;
patterning the first metallic material layer to form a first set of pillars having a first height dimension;
forming a photoresist mask over the first set of pillars in a first region of the interposer while exposing a second region of the interposer;
depositing a second metallic material layer over the exposed second region; and
patterning the second metallic material layer to form a second set of pillars having a second height dimension greater than the first height dimension.

18. The method of claim 16, wherein the dielectric polymer material comprises at least one of polyimide, benzocyclobutene, or polybenzobisoxazole, and wherein the layers of the dielectric polymer material are deposited using a spin coating and drying process.

19. The method of claim 16, wherein the conductive material comprises copper, and wherein the metallization process comprises at least one of physical vapor deposition, sputtering, chemical vapor deposition, atomic layer deposition, plasma-enhanced chemical vapor deposition, or electrochemical deposition.

20. The method of claim 16, further comprising:
adhering the interposer to the first carrier substrate using a first release layer comprising a light-to-heat conversion material;
irradiating the first release layer with optical radiation to cause the light-to-heat conversion material to heat up and lose adhesion; and
separating the first carrier substrate from the interposer after the first release layer loses adhesion.
